(19) United States
(12) Patent Application Publication
(10) Pub. No.: US 2024/0321572 A1
(43) Pub. Date: Sep. 26, 2024

(54) SEMICONDUCTOR DEVICE AND METHOD FOR MANUFACTURING THE SAME

(71) Applicant: Taiwan Semiconductor Manufacturing Company, Ltd., Hsinchu (TW)

(72) Inventors: Li-Fong Lin, Hsinchu (TW); Yen-Chun Huang, Taipei (TW); Zhen-Cheng Wu, Hsinchu (TW); Chi On Chui, Hsinchu (TW); Chih-Tang Peng, Zhubei (TW); Yu Ying Chen, Taoyuan (TW)

(73) Assignee: Taiwan Semiconductor Manufacturing Company, Ltd., Hsinchu (TW)

(21) Appl. No.: 18/186,778

(22) Filed: Mar. 20, 2023

(51) Int. Cl. H01L 21/02; H01L 21/28; H01L 21/762

(52) U.S. Cl. CPC H01L 21/0228; H01L 21/0217; H01L 21/28123; H01L 21/76224

(57) ABSTRACT

Provided are semiconductor devices and methods for manufacturing semiconductor devices. A method deposits conformal material to form a conformal liner in the trench and modifies the conformal liner such an upper liner portion is modified more than a lower liner portion. The deposition and modifying steps are repeated while a rate of deposition of the conformal material over a non-modified surface of the conformal liner is faster than a rate of deposition of the conformal material over a modified surface of the conformal liner to form a remaining unfilled gap with a V-shape. The method further includes depositing a conformal material in the remaining unfilled gap.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

One fundamental aspect of semiconductor fabrication is the formation of and filling of trenches. Scaling of IC dimensions presents particular challenges for filling trenches, especially high-aspect trenches.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a plan view of a layout of a device, in accordance with some embodiments.

FIG. 2 is a flow chart illustrating a method, in accordance with some embodiments.

FIGS. 3-7 are cross-sectional views of a device including a trench during successive stages of fabrication of the method of FIG. 2, in accordance with some embodiments.

FIG. 8 is a focused view of the modified layer of FIG. 6.

FIG. 9 is a flow chart illustrating a method, in accordance with some embodiments.

FIGS. 10-15 are cross-sectional views of a device including a trench during successive stages of fabrication of the method of FIG. 9, in accordance with some embodiments.

FIG. 16 is a flow chart illustrating a method, in accordance with some embodiments.

FIGS. 17-20 are cross-sectional views of a device including a trench during successive stages of fabrication of the method of FIG. 16, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “over”, “overlying”, “above”, “upper”, “top”, “under”, “underlying”, “beneath”, “below”, “lower”, “bottom”, “side”, and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In certain embodiments herein, a “material layer” is a layer that includes at least 51 wt. % of the identified material, for example at least 60 wt. % of the identified material, or at least 75 wt. % of the identified material, or at least 90 wt. % of the identified material; and a layer that is a “material” includes at least 51 wt. % of the identified material, for example at least 60 wt. % of the identified material, at least 75 wt. % of the identified material, or at least 90 wt. % of the identified material. For example, certain embodiments, each of a titanium nitride layer and a layer that is titanium nitride is a layer that is at least 51 wt. %, at least 60 wt. %, at least 75 wt. %, titanium nitride, or at least 90 wt. % titanium nitride.

For the sake of brevity, conventional techniques related to conventional semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

It is also noted that this disclosure presents certain embodiments in the form of multi-gate transistors. Multi-gate transistors include those transistors whose gate structures are formed on at least two-sides of a channel region. These multi-gate devices may include a P-type metal-oxide-semiconductor device or an N-type metal-oxide-semiconductor multi-gate device. Specific examples may be presented and referred to herein as FINFET, on account of their fin-like structure. Also presented herein are embodiments of a type of multi-gate transistor referred to as a gate-all-around (GAA) device. A GAA device includes any device that has its gate structure, or portion thereof, formed on 4-sides of a channel region (e.g., surrounding a portion of a channel region). Devices presented herein also include embodiments that have channel regions disposed in nanosheet channel(s), nanowire channel(s), bar-shaped channel(s), and/or other suitable channel configurations. Herein, “nanosheet channel” is intended to include nanowire channel and bar-shaped channel configurations.

Presented herein are embodiments of methods for filling trenches. In certain embodiments, methods may fill trenches with a material deposited by atomic layer deposition (ALD). In such embodiments, a seam may be formed in the deposited material. In certain embodiments, the seam has a width of less than 1.5 nanometers (nm).

In certain embodiments, the trenches may be formed and filled in a continuous poly on diffusion edge (CPODE) process. For purposes of this disclosure, a “diffusion edge” may be equivalently referred to as an active edge, where for example an active edge abuts adjacent active regions. Further, an active region includes a region where transistor structures are formed (e.g., including source, drain, and gate/channel structures). In some examples, active regions may be disposed between insulating regions. The CPODE process may provide an isolation region between neighboring active regions (e.g., device regions including source, drain, and gate structures), and thus neighboring transistors, by performing a dry etching process along an active edge (e.g., at a boundary of adjacent active regions) to form a cut region and filling the cut region with a dielectric.

Before the CPODE process, the active edge may include a GAA dummy structure having a gate stack and a plurality of channels (e.g., nanosheet channels). The plurality of channels may each include a chemical oxide layer formed thereon, and high-K dielectric/metal gate layers may be formed over the chemical oxide layer and between adjacent channels of the plurality of channels. In addition, inner spacers may be disposed between adjacent channels at lateral ends of the plurality of channels. In various examples, source/drain epitaxial (epi) layers of adjacent active regions are disposed on either side of the GAA dummy structure (formed at the active edge), such that the adjacent source/drain epi layers are in contact with the inner spacers and plurality of channels of the GAA dummy structure.

Thus, in certain embodiments, trench may extend vertically (in a Z-direction) through a gate material and into the semiconductor substrate, for example for providing an isolation region between adjacent gate structures. Such an isolation region may extend laterally (in an X-direction) in a direction perpendicular to gate lines. Alternatively, a trench may extend vertically (in a Z-direction) through isolation material between gate structures and into the semiconductor substrate, such as for providing an isolation region between adjacent source/drain active regions. Such an isolation region may extend laterally (in a Y-direction) in a direction parallel to gate lines.

While trenches may be described or illustrated as related to edge CPODE processing, one of ordinary skill would recognize that the teaching can apply to filling trenches that are formed at various stages of semiconductor fabrication. Thus, there are many examples of semiconductor devices that may benefit from aspects of the present disclosure.

Embodiments of the present disclosure offer advantages over related art, though it is understood that other embodiments may offer different advantages, not all advantages are necessarily discussed herein, and no particular advantage is required for all embodiments. For example, embodiments discussed herein include methods for filling trenches with dielectric material to form isolation regions. Embodiments herein provide for reducing the amount of void space within the dielectric-filled trenches. Reduction in void space may improve the isolation performance of the dielectric-filled trenches. Further, an improved trench filling process may reduce the risk of shorts between conductive regions.

Avoiding the formation of voids is particularly difficult for high aspect ratio trenches and/or for trenches that have bottle-shaped profiles, i.e., trenches which have a wider lower portion and a narrower upper portion. For such trenches, known deposition processes may fill the upper portion such that new deposition material cannot reach unfilled regions of the lower portion. Some known processes may utilize high thermal budgets and long process times in order to reduce the likelihood of void formation. Methods provided herein may reduce the formation of voids in dielectric-filled trenches more efficiently, at a lower thermal budget, and/or with shorter required processing times.

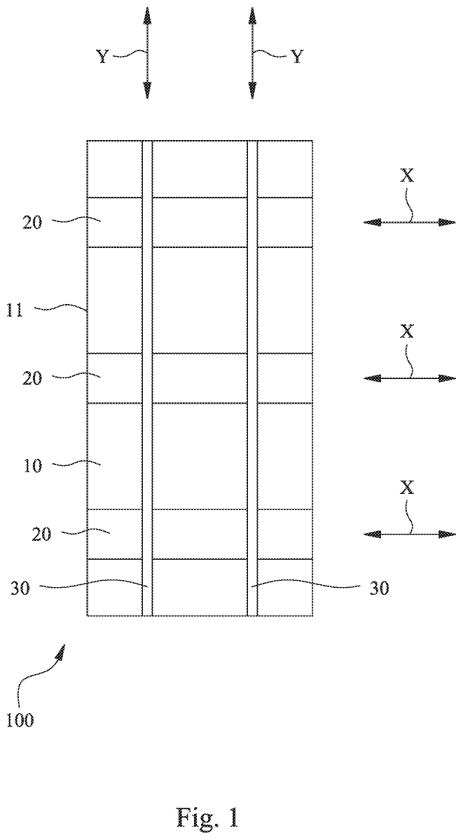

For purposes of the discussion that follows, FIG. 1 provides a simplified top-down layout view of a device 100. In various embodiments, the device 100 may be a multi-gate device and/or may include a FinFET device, a GAA transistor, or other type of multi-gate device. The device 100 is formed over a substrate 10. In some embodiments, the substrate 10 may be a semiconductor substrate such as a silicon substrate. The substrate 10 may include various layers, including conductive or insulating layers formed on a semiconductor substrate. The substrate 10 may include various doping configurations depending on design requirements as is known in the art. The substrate 10 may also include other semiconductors such as germanium, silicon carbide (SiC), silicon germanium (SiGe), or diamond. Alternatively, the substrate 10 may include a compound semiconductor and/or an alloy semiconductor. Further, the substrate 10 may optionally include an epi layer, may be strained for performance enhancement, may include a silicon-on-insulator (SOI) structure, and/or have other suitable enhancement features.

FIG. 1 illustrates a unit cell 11, i.e., a portion of the semiconductor substrate 10. As shown, parallel active regions 20 are spaced apart from one another and extend in an X-direction. Further, parallel gate lines 30 are spaced apart from one another and extend in a Y-direction perpendicular to the X-direction. In certain embodiments, gate lines 30 are formed from conductive material such as metal and form gate structures for devices 100.

In embodiments herein, a cut region or trench may be formed across an active region 20 and extend in the Y-direction, i.e., parallel to the gate lines 30. Additionally or alternatively, a cut region or trench may be formed across a gate line 30 and extend in the X-direction, i.e., perpendicular to the gate lines 30 and parallel to the active regions 20. In certain embodiments, the cut region or trench is filled with dielectric material to form an isolation region. Such isolation region may isolate adjacent devices from one another.

Methods for filling trenches are described in relation to the Figures. In some embodiments, the methods may be used to fabricate the device 100, described above with reference to FIG. 1. Thus, one or more aspects discussed above with reference to the device 100 may also apply to methods described below. It is understood that each method includes steps having features of a complementary metal-oxide-semiconductor (CMOS) technology process flow and thus, are only described briefly herein. Also, additional steps may be performed before, after, and/or during each method.

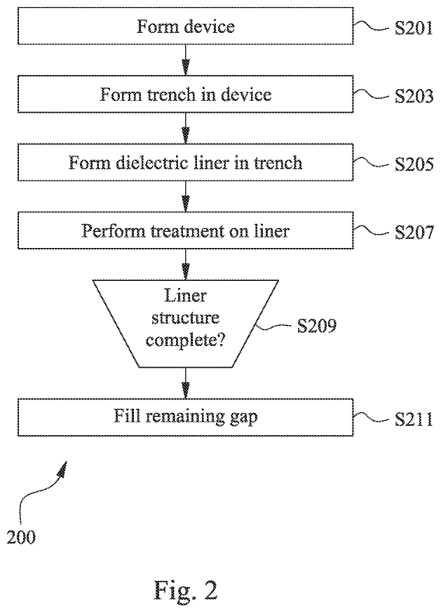

Referring now to FIGS. 2-9, a method 200 for fabricating a semiconductor device is described, in accordance with various embodiments. In some embodiments, method 200 may be used to fabricate the device 100, described above with reference to FIG. 1. Thus, one or more aspects discussed above with reference to the device 100 may also apply to method 200. It is understood that method 200 includes steps having features of a complementary metal-oxide-semiconductor (CMOS) technology process flow and thus, are only described briefly herein. Also, additional steps may be performed before, after, and/or during method 200.

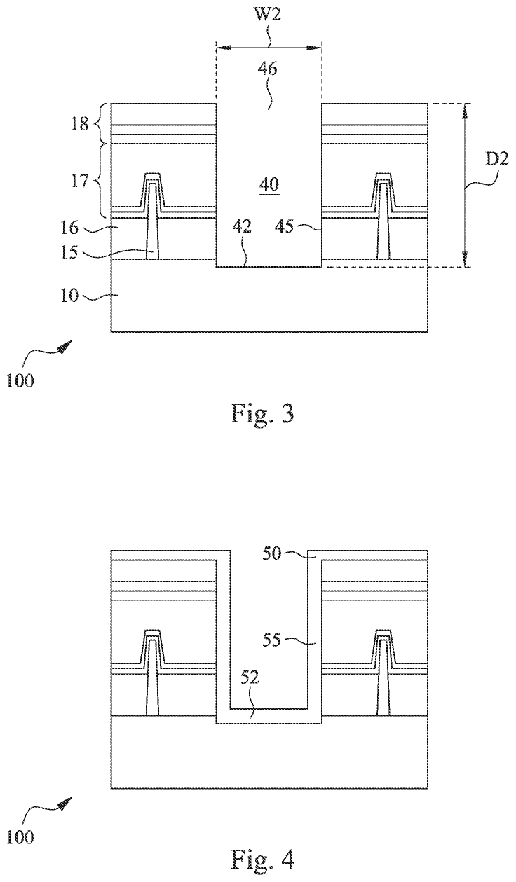

FIG. 2 provides a flow chart for another method 200 for filling a trench. Method 200 is described below with reference to FIGS. 3-7 which illustrate the semiconductor device 100 at various stages of fabrication according to method 200 and to FIG. 8, which is a focused view of the modified layer of FIG. 6. FIGS. 3-8 provide cross-sectional views of an embodiment of the semiconductor device 100 along a plane substantially parallel to a plane defined by a Y-axis in FIG. 1 passing through a gate line 30, such as a metal gate line.

It is noted that, while the formation of gaps or voids during trench fill by atomic layer deposition (ALD) may be unavoidable, method 200 reduces gap and void formation during ALD by depositing material in a V-shaped trench having a narrow bottom and a wide trench opening. The wide trench opening may also prevent the re-entrance condition.

Cross-referencing FIGS. 2 and 3, method 200 includes, at S201, forming a device 100 over substrate 10, including forming fin structures 15 over and/or from the substrate 10, forming isolation 16, such as a shallow trench isolation, around the fin structures 15, forming gate layers 17, such as gate dielectric and gate electrode layers over the fin structures 15, and forming mask layers 18 over the gate layers 17.

Method 200 further includes, at S203, forming a trench 40 in the device 100. As shown in FIG. 3, trench 40 includes a trench bottom 42 and sidewalls 45 extending up from the trench bottom 42 to an opening 46. In certain embodiments, the trench 40 is formed by patterning the mask layers 18 and then etching through the gate layers 17, through the isolation 16 and into the substrate 10. In certain embodiments, the trench 40 is formed by a dry etch process, for example, reactive ion or plasma etching. The trench 40 may be formed during a cut metal gate process.

The trench 40 may be formed with a maximum depth D2 and a maximum width (or critical dimension) W2. In certain embodiments, the maximum depth D2 is from 150 to 200 nanometers (nm). In certain embodiments, the maximum width W2 is from 10 to 30 nanometers (nm). In certain embodiments, trench 40 has a height/width aspect ratio of from 5/1 to 20/1.

As shown in FIG. 3, the sidewalls 45 of the trench 40 are formed by the mask layers 18, gate layers 17, isolation 16, and a portion of the substrate 10. Further, the trench bottom 42 is formed by the substrate 10.

Method 200 may further include a cut metal refill process. For example, cross-referencing FIGS. 2 and 4, method 200 further includes, at S205, forming a dielectric liner 50 over the structure of device 100, including in the trench 40. Specifically, the dielectric liner 50 is formed by a conformal deposition process. For example, the dielectric liner 50 may be formed by atomic layer deposition (ALD). In certain embodiments, the dielectric liner 50 is a silicon nitride layer that is formed by an ALD process performed at a temperature of from 400 to 600° C. In other embodiments, the dielectric liner 50 is silicon nitride or silicon oxide.

As shown, the dielectric liner 50 includes sidewall portions 55 that are formed on the sidewalls 45 of the trench 40 and a bottom portion 52 that is formed on the trench bottom 42.

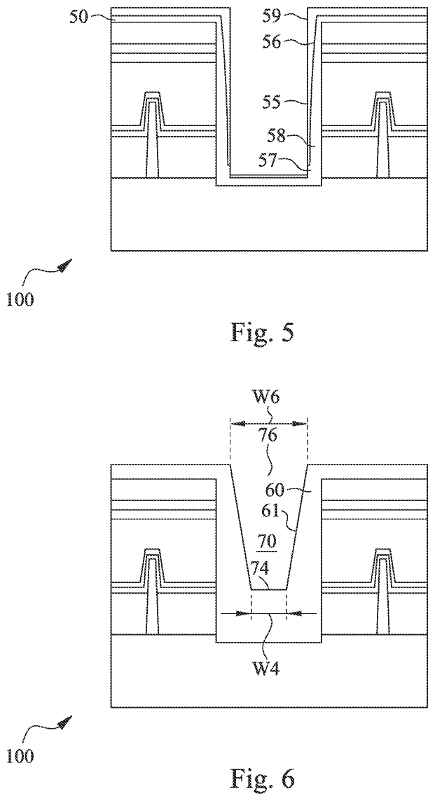

Cross-referencing FIGS. 2 and 5, method 200 continues, at S207, with performing a treatment to modify the conformal liner 50. In certain embodiments, the treatment is an inhibition treatment that modifies the properties of the conformal liner 50.

In certain embodiments, the treatment modifies the liner 50 in a non-uniform manner. Specifically, the treatment modifies an upper portion 56 of the conformal liner 50 more than a lower portion 58 of the conformal liner 50. Further, the amount of modification may decrease downward along the depth of the sidewall portions 55 in a gradient.

In certain embodiments, the treatment is a plasma treatment in which a gas is ionized and contacted with the conformal liner to incorporate at least one additional element into the conformal liner. For example, a nitrogen/hydrogen (N₂/H₂) plasma is formed by ionizing N₂/H₂ gas and flowed into contact with the conformal liner. The ions contact and alter the surface properties of the conformal liner 50—creating a modified layer or sublayer 59 at the exterior surface of the conformal liner 50. Locations 57 where the ions do not contact the surface of the conformal liner 50 remain unmodified. During this process, more of the nitrogen and/or hydrogen ions contact the upper portion 56 of the conformal liner 50 and less of the nitrogen and/or oxygen ions contact the lower portion 58 of the conformal liner 50. As a result, more of the upper portion 56 of the conformal liner 50 undergoes surface treatment and less of the lower portion 58 of the conformal liner 50 undergoes surface treatment. Thus, the modified sublayer 59 may be absent from the sidewall portions 55 in the lower portion 58 of the conformal liner 50 or may have a minimum thickness in the sidewall portions 55 in the lower portion 58 of the conformal liner 50. The thickness of the modified sublayer 59 in the sidewall portion 55 increases as the sidewall portion 55 extends upward in the Z-direction. Thus, the modified sublayer 59 in the sidewall portion 55 has a maximum thickness at the opening 46 of the trench 40.

Cross-referencing FIGS. 2, 4 and 5, method 200 may continue by repeating actions at S205 and S207 to form additional layers of conformal material and to modify the additional layers. In certain embodiments, depositing dielectric material over the modified liner results in a differential deposition rate. Specifically, the deposition rate of the dielectric material over the non-modified surface of the conformal liner 50, such as in the lower portion 58, is faster than a rate of deposition of the conformal material over the modified surface 59 of the conformal liner 50. In this manner, the bottom of the trench is narrowed at a faster rate than the upper region of the trench.

Repeating the actions at S205 and S207 for a selected number of cycles results in the formation of the structure of the device 100 in FIG. 6. Specifically, the initial and additional conformal liners together form a liner structure 60 with sloping sidewalls 61 that define a remaining unfilled gap 70 with a V-shape. As shown, the gap 70 has a narrow bottom 74 with a width W4 and a wider opening 76 with a width W6 greater than W4.

Method 200 provides for repeating the actions at S205 and S207 by inquiring at inquiry S209 whether the liner structure 60 is complete. If not, method 200 continues at action S205. When the liner structure 60 is complete, i.e., after a selected number of cycles of the deposition and treatment processes of S205 and S207 to form the liner structure 60 with sloping sidewalls 61 defining the remaining unfilled gap 70 with a V-shape, the method 200 may continue at S211.

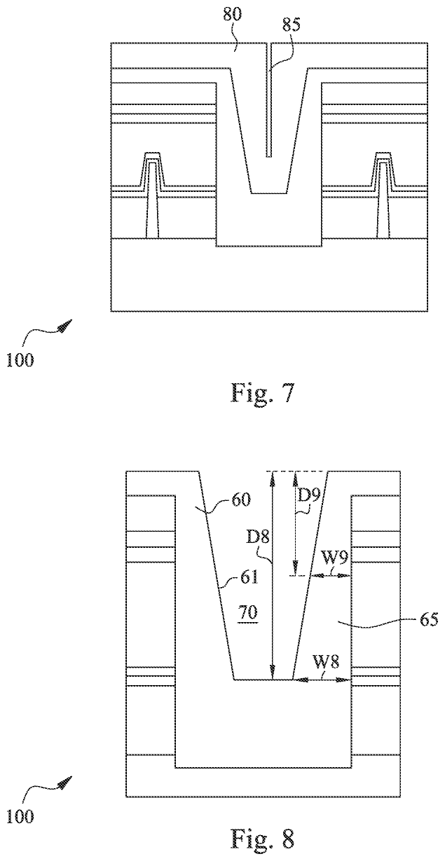

At S211, the method 200 includes depositing a conformal material 80 to fill the remaining unfilled gap 70. In certain embodiments, the conformal material 80 is a dielectric material such as silicon nitride or silicon oxide. In certain embodiments, the conformal material 80 is not the same material as the liner structure 60. In certain embodiments, the conformal material 80 is deposited by an ALD process. With the wider opening 76 and narrow bottom 74 of the gap 70, the process for depositing the conformal material 80 results in a reduction in void formation. Specifically, the conformal material 80 is formed with a V-shaped bottom surface on the sloping sidewalls 61 of the liner structure 60. As the conformal material 80 is built off of the sloping sidewalls 61, conformal material grows in a direction perpendicular to the sloping sidewalls 61. As shown in FIG. 7, a seam 85 may remain unfilled by the conformal material 80. In certain embodiments, the seam 85 has a width or critical dimension of less than 3 nanometers (nm), for example less than 2 nanometers (nm), such as less than 1.5 nanometers (nm).

FIG. 8 provides an enlarged view of the liner structure 60 and unfilled gap 70 of FIG. 6. As shown, the gap 70 has a maximum vertical depth D8, in the Z-direction from the gap opening 76 to the bottom 74. At the vertical depth D8, the sidewall portion 65 of the liner structure 60 has a lateral thickness or width W8. In FIG. 8, vertical depth D9 is half of depth D8. At the vertical depth D9, the sidewall portion 65 of the liner structure 60 has a lateral thickness or width W9.

In certain embodiments, the slope of sidewall 61 of the liner structure 60 is generally linear. The slope of the sidewall 61 of the liner structure 60 may be defined by the ratio of width W8 and width W9. In certain embodiments in which trench critical dimension W2 (shown in FIG. 3) is or is greater than 25 nanometers (nm), W8 is greater than 1.3 times W9. In certain embodiments in which trench critical dimension W2 (shown in FIG. 3) is less than 25 nanometers (nm), W8 is greater than 1.1 times W9.

Method 200 as described in FIGS. 2-8 provides for filling the trench 40 such that voids therein are reduced.

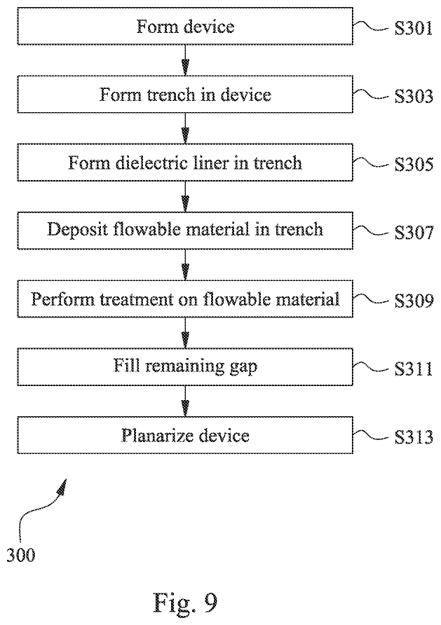

Referring now to FIGS. 9-15, a method 300 for fabricating a semiconductor device is described, in accordance with various embodiments. In some embodiments, method 300 may be used to fabricate the device 100, described above with reference to FIG. 1. Thus, one or more aspects discussed above with reference to the device 100 may also apply to method 300. It is understood that method 300 includes steps having features of a complementary metal-oxide-semiconductor (CMOS) technology process flow and thus, are only described briefly herein. Also, additional steps may be performed before, after, and/or during method 300.

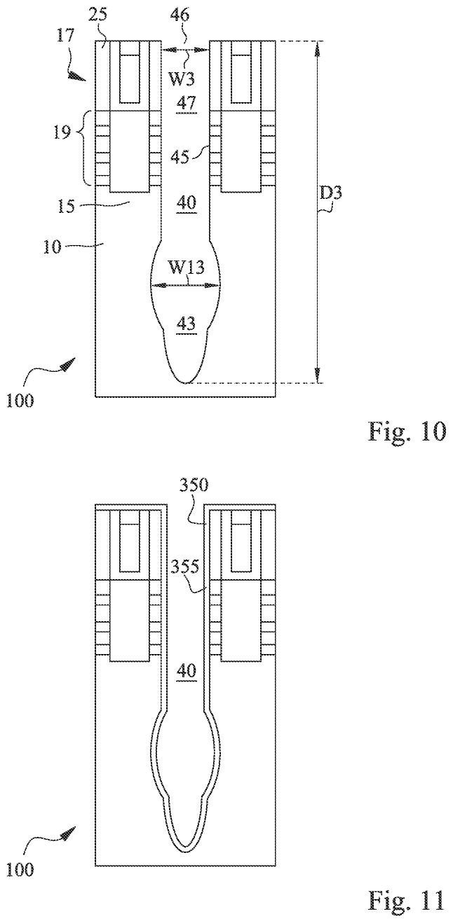

FIG. 9 provides a flow chart for another method 300 for filling a trench. Method 300 is described below with reference to FIGS. 10-15 which illustrate the semiconductor device 100 at various stages of fabrication according to method 300. FIGS. 10-15 provide cross-sectional views of an embodiment of the semiconductor device 100 along a plane substantially parallel to a plane defined by an X-axis in FIG. 1 passing through an active region 20.

Cross-referencing FIGS. 9 and 10, method 300 includes, at S301, forming a device 100 over substrate 10, including forming fin structures 15 over and/or from the substrate 10, forming isolation such as a shallow trench isolation, around the fin structures 15 (in front of and being the fin structure 15 of FIG. 10), forming gate layers 17, such as gate dielectric and gate electrode layers over the fin structures 15, and forming mask layers (not shown in FIG. 10) over the gate layers 17. As shown in FIG. 10, the fin structures 15 may be formed with nanosheet layers, collectively identified by reference number 19. Further, forming the device 100 may include forming an inter-layer dielectric (ILD) layer 25 over the device 100, including between gate lines formed by the gate layers 17.

Method 300 further includes, at S303, forming a trench 40 in the device 100. As shown in FIG. 3, trench 40 includes a lower portion 43 located in the substrate 10 and an upper portion 47 located in the fin structure 15 and ILD layer 25. The trench 40 includes sidewalls 45 extending up from the lower portion 43 to an opening 46. In certain embodiments, the trench 40 is formed by patterning mask layers and then etching through the ILD layer 25, the nanosheet layers 19 and fin structure 15, and into the substrate 10. In certain embodiments, the trench 40 is formed by a dry etch process, for example, reactive ion or plasma etching.

The trench 40 may be formed with a maximum depth D3, an opening width (or critical dimension) W3, and a maximum width W13.

As shown, the maximum width W13 is located in the lower portion 43 of the trench 40 while the upper portion 47 of the trench 40 has narrower opening width W3. Thus, the trench 40 is provided with a bottle shape or a bowing profile. In certain embodiments, the maximum depth D3 is from 100 to 250 nanometers (nm). In certain embodiments, the opening width W3 is from 15 to 30 nanometers (nm). In certain embodiments, the maximum width W13 is from 1 to 6 nanometers (nm) greater than the opening width W3. In certain embodiments, trench 40 has a height/width aspect ratio of from 10/3 to 51/3 based on the opening width W3.

As shown in FIG. 10, the sidewalls 45 of the trench 40 are formed by the ILD layer 25, the nanosheet layers 19, the fin structure 15, and a portion of the substrate 10. Further, the lower portion 43 of the trench 40 is surrounded by the substrate 10.

Cross-referencing FIGS. 9 and 11, method 300 may further include, at S305, optionally forming a liner 350 over the structure of device 100, including in the trench 40. In certain embodiments, liner 350 is formed by a conformal deposition process. For example, the liner 350 may be formed by atomic layer deposition (ALD). In certain embodiments, the liner 350 an oxidation barrier dielectric layer. For example, the liner 350 may be formed from silicon nitride (SiN) or silicon carbon nitride (SiCN), or another suitable material. In certain embodiments, the liner 350 is formed by an ALD process performed at a temperature of from 400 to 630° C. As shown, the dielectric layer 350 includes sidewall portions 355 that are formed on the sidewalls 45 of the trench 40.

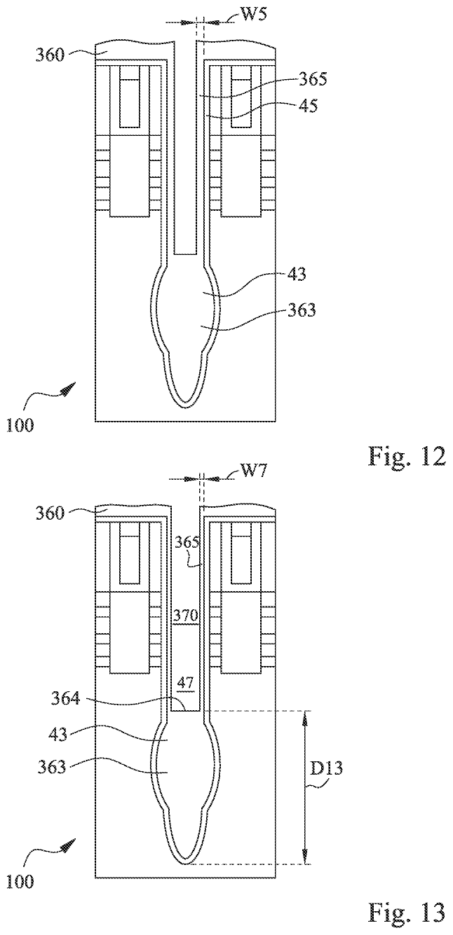

Cross-referencing FIGS. 9 and 12, method 300 continues, at S307, with depositing a flowable material 360 to fill the lower portion 43 of the trench 40. In certain embodiments, the flowable material is a dielectric material, such as silicon oxide (SiO) or another suitable material. The deposition process introduces the material as a viscous fluid-like state such that the material fills the lower portion 43 of the trench 40 while covering the sidewalls 45 of the trench 40. In certain embodiments, the deposition process is performed at a temperature of from 50 to 150° C.

As a result, the flowable material 360 forms a bottom plug 363 in the lower portion 43 of the trench 40 and forms sidewall members 365 adjacent to the sidewalls 45 of the trench 40, and to the sidewall portions 355 of the dielectric layer 350 if present. As shown, the sidewall members 365 have an initial width or thickness W5. In certain embodiments, the bottom plug 363 is void-free, i.e., seam-free.

Cross-referencing FIGS. 9 and 13, method 300 continues, at S309, with performing a treatment on the partially fabricated device 100 to shrink the flowable material 360. In certain embodiments, the treatment includes performing an ultraviolet (UV) treatment and/or a thermal anneal treatment. In certain embodiments, the ultraviolet (UV) treatment is performed with ultraviolet (UV) light at a temperature of from 5 to 50° C., for a duration of from 1 to 10 minutes, and with a wavelength of from 200 to 400 nanometers (nm). In certain embodiments, the thermal anneal treatment is performed with wet steam (H₂O) at a temperature of from 400 to 700° C. During the thermal treatment, the silicon-hydrogen bonds may be broken and silicon-oxygen and/or silicon-hydroxide bonds may form. As a result of the treatment, the thickness of the sidewall members 365 is reduced from the initial thickness W5 to a reduced thickness W7. In certain embodiments, reduced thickness W7 is from 3 to 20% less than the initial thickness W5.

As shown, despite the shrinkage of the flowable material 360, in certain embodiments the lower portion 43 of the trench 40 remains completely filled by the bottom plug 363. In other words, a top surface 364 of the bottom plug 363 remains located within the narrow upper portion 47 of the trench 40. In certain embodiments, the top surface 364 of the bottom plug 363 may recede slightly into the lower portion 43 of the trench 40. If the top surface 364 of the bottom plug 363 is located in the lower portion 43 of the trench 40, in certain embodiments, the top surface 364 of the bottom plug 363 distanced from the upper portion 47 by a distance that is less than half of the critical dimension W3.

As shown, the bottom plug 363 has a vertical thickness (in the Z-direction) or height D13 of from 50 to 120 nanometers (nm). In certain embodiments, the bottom plug 363 has a height D13 of from 50 to 80 nanometers (nm), of from 65 to 100 nanometers (nm), or of from 80 to 120 nanometers (nm).

To verify the re-entrance level (W13-W3) effect to flowable height D13, W13-W3 is from 1 to 6 nm, D13 will verify from 0% (80 to 120 nm) to −20% (65 to 100 nm) height. As for the CD width effect, if W3 is from 15 to 30 nm, D13 will verify from 0% (80 to 120 nm) to −40% (50 to 80 nm) height. In an embodiment, 0% D13 height equals 80 to 120 nm and is defined as the condition when W13 and W3 equal 15 nm.

As further shown, a remaining unfilled gap 370 is defined in the trench 40, above the bottom plug 363 and inside the sidewall members 365.

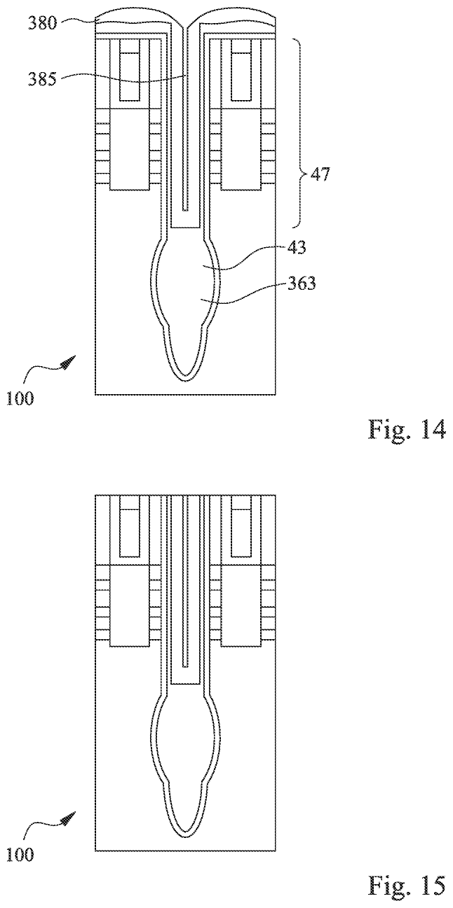

Cross-referencing FIGS. 9 and 14, method 300 continues, at S311, with depositing a conformal material 380 in the remaining unfilled gap 370. In certain embodiments, depositing the conformal material 380 in the remaining unfilled gap 370 includes depositing silicon nitride by an atomic layer deposition (ALD) process. In certain embodiments, the ALD process is controlled for a higher degree of conformality, such as compared with the earlier deposition process. In certain embodiments, the highly conformal deposition process is an ALD process performed at a temperature of from 400 to 630° C.

As shown in FIG. 14, a seam 385 may remain unfilled by the conformal material 380. In certain embodiments, the seam 385 has a width or critical dimension of less than 3 nanometers (nm), for example less than 2 nanometers (nm), such as less than 1.5 nanometers (nm). Further, the seam 385 is located only within the upper portion 47 of the trench 40. For example, the lower portion 43 of the trench 40 may be completely filled by the bottom plug 363 of the flowable material 360, or the lower portion 43 of the trench 40 may be completely filled by the bottom plug 363 of the flowable material 360 and by the atomic layers of the conformal material 380 deposited laterally over the top surface 364 of the bottom plug 363. In certain embodiments, the seam 385 is distanced from the bottom plug 363 and lower portion 43 of the trench 40 by a distance of greater than 2 nanometers (nm), such as greater than 4 nanometers (nm), for example greater than 6 nanometers (nm), such as greater than 8 nanometers (nm), or greater than 10 nanometers (nm).

Cross-referencing FIGS. 9 and 15, method 300 continues, at S313, with planarizing device 100. For example, a chemical mechanical polishing (CMP) process may be performed to remove the liner 350, if present, the flowable material 360, and the conformal material 380 located over the trench 40.

Method 300, as described in FIGS. 9-15 provides for filling trench 40 such that voids therein are reduced. Further, the seam 385 is distanced from the lower portion 43 of the trench 40, such that the device 100 has a seam free bottom dielectric region that may be formed solely of bottom plug 363 or of bottom plug 363 and a scam free portion of the conformal material 380 built by laterally deposited layers over the top surface 364 of the bottom plug 363. Method 300 may be described as a method for gap filling using a bilayer film, with each layer formed by different processes. Further, the depth profile layer to layer oxygen/nitrogen ratio, i.e., the layer-to-layer difference along the depth, can be used to identify a bilayer film formed by method 300. In certain embodiments, the void-free or seam-free bottom plug 363 is indicative of the bilayer film formed by method 300. Further, method 300 provides a process for reducing void formation during gap fill of a trench 40 with a bowing profile.

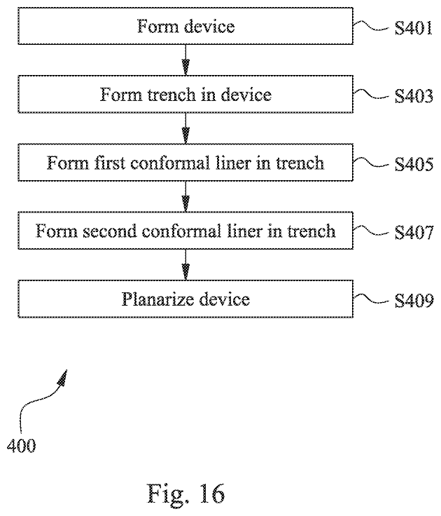

Referring now to FIGS. 16-20, a method 400 for fabricating a semiconductor device is described, in accordance with various embodiments. In some embodiments, method 400 may be used to fabricate the device 100, described above with reference to FIG. 1. Thus, one or more aspects discussed above with reference to the device 100 may also apply to method 400. It is understood that method 400 includes steps having features of a complementary metal-oxide-semiconductor (CMOS) technology process flow and thus, are only described briefly herein. Also, additional steps may be performed before, after, and/or during method 400.

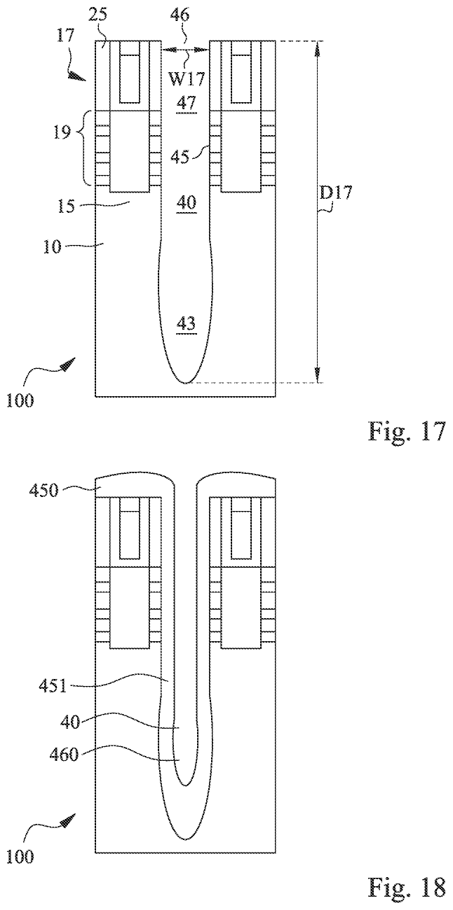

FIG. 16 provides a flow chart for another method 400 for filling a trench. Method 400 is described below with reference to FIGS. 17-20 which illustrate the semiconductor device 100 at various stages of fabrication according to method 400. FIGS. 17-20 provide cross-sectional views of an embodiment of the semiconductor device 100 along a plane substantially parallel to a plane defined by an X-axis in FIG. 1 passing through an active region 20.

Cross-referencing FIGS. 16 and 17, method 400 includes, at S401, forming a device 100 over substrate 10, including forming fin structures 15 over and/or from the substrate 10, forming isolation such as a shallow trench isolation, around the fin structures 15 (in front of and being the fin structure 15 of FIG. 17), forming gate layers 17, such as gate dielectric and gate electrode layers over the fin structures 15, and forming mask layers (not shown in FIG. 10) over the gate layers 17. As shown in FIG. 17, the fin structures 15 may be formed with nanosheet layers, collectively identified by reference number 19. Further, forming the device 100 may include forming an inter-layer dielectric (ILD) layer 25 over the device 100, including between gate lines formed by the gate layers 17.

Method 400 further includes, at S403, forming a trench 40 in the device 100. As shown in FIG. 3, trench 40 includes a lower portion 43 located in the substrate 10 and an upper portion 47 located in the fin structure 15 and ILD layer 25. The trench 40 includes sidewalls 45 extending up from the lower portion 43 to an opening 46. In certain embodiments, the trench 40 is formed by patterning mask layers and then etching through the ILD layer 25, the nanosheet layers 19 and fin structure 15, and into the substrate 10. In certain embodiments, the trench 40 is formed by a dry etch process, for example, reactive ion or plasma etching.

The trench 40 may be formed with a maximum depth D17, and a width (or critical dimension) W17. In certain embodiments, maximum depth D17 may be from 200 to 250 nanometers (nm). In certain embodiments, width W17 may be from 10 to 20 nanometers (nm). In certain embodiments, the trench may have a height/width aspect ratio of from 10/1 to 25/1.

As shown in FIG. 17, the sidewalls 45 of the trench 40 are formed by the ILD layer 25, the nanosheet layers 19, the fin structure 15, and a portion of the substrate 10.

Cross-referencing FIGS. 16 and 18, method 400 may further include, at S405, depositing a conformal material 450 to form a conformal liner 451 in the trench 40. In certain embodiments, the conformal material 450 is silicon nitride or another suitable dielectric material. In certain embodiments, the conformal material 450 is deposited by an atomic layer deposition (ALD) process. In certain embodiments, the conformal material 450 is deposited at a temperature of from 510 to 600° C. In certain embodiments, the conformal material 450 is deposited at a deposition rate of 8 to 10 wafers per hour (WPH). In certain embodiments, the conformal material 450 is silicon nitride and is silicon rich. For example, in certain embodiments, the conformal material 450 has a silicon:nitrogen ratio of from 1:1 to 1.2:1. In certain embodiments, the conformal material 450 is formed as a relatively higher quality film with a relatively slower deposition rate and relatively higher temperature.

As shown in FIG. 18, after forming the conformal liner 451, a remaining unfilled gap 460 is defined in the trench 40 inside the conformal liner 451.

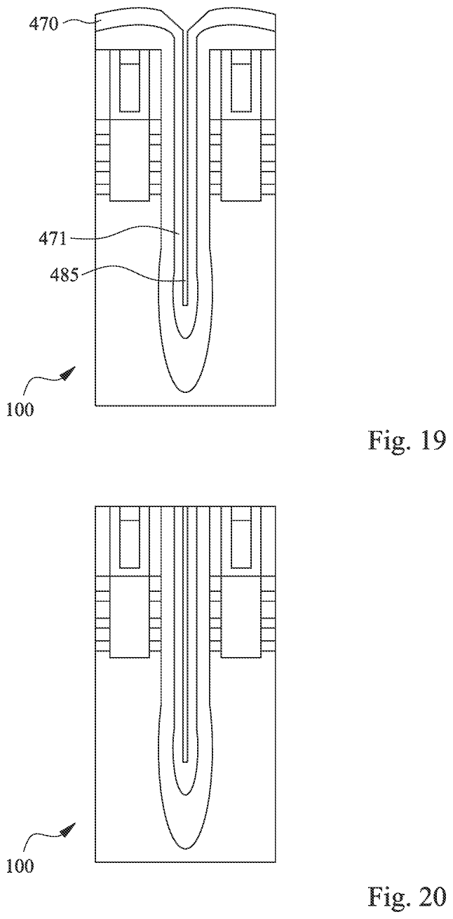

Cross-referencing FIGS. 16 and 19, method 400 may further include, at S407, depositing a conformal material 470 to form a conformal liner 471 in the gap 460 in the trench 40. In certain embodiments, the conformal material 470 is silicon nitride or another suitable dielectric material. In certain embodiments, the conformal material 470 is deposited by an atomic layer deposition (ALD) process. In certain embodiments, the conformal material 470 is deposited at a temperature of from 400 to 450° C. In certain embodiments, the conformal material 470 is deposited at a deposition rate of 10 to 15 wafers per hour (WPH). In certain embodiments, the conformal material 470 is silicon nitride and is nitrogen rich. For example, in certain embodiments, the conformal material 470 has a silicon:nitrogen ratio of from 0.8:1 to 1:1. In certain embodiments, the conformal material 470 is formed with a relatively higher deposition rate and relatively lower temperature to reduce device thermal budge.

Thus, at S407, conformal material 470 is deposited at a deposition rate greater than the deposition rate of conformal material 450 and at a temperature lower than the temperature at which conformal material 450 was deposited.

Generally, the conformal liner 451 may be considered to be a slow growth, high quality film. Generally, the conformal liner 471 may be considered to be a fast growth, lower quality film. Conformal material 450 may be considered to be a high temperature conformal material; and conformal material 470 may be considered to be a low temperature conformal material.

As shown in FIG. 19, a seam 485 may remain unfilled by the conformal material 470. In certain embodiments, the seam 485 has a width or critical dimension of less than 1.5 nanometers (nm).

Cross-referencing FIGS. 16 and 20, method 400 continues, at S409, with planarizing device 100. For example, a chemical mechanical polishing (CMP) process may be performed to remove the conformal liner 451 and the conformal liner 471 located over the trench 40.

Method 400, as described in FIGS. 16-20 provides for filling trench 40 such that voids therein are reduced. Further, method 400 provides for a lower thermal budget and shorter process time as compared to certain methods that fail to use the two different conformal liners. In addition, method 400 may provide for a lower risk of thermal effects, such as oxide diffusion. Method 400 may be described as a method for gap filling using a bilayer film, with each layer formed by different processes. Further, the bilayer film formed by method 400 may exhibit an identifiable layer to layer silicon:nitrogen ratio.

Thus, one of the embodiments of the present disclosure describes a method for filling a trench. The method includes (a) depositing conformal material to form a conformal liner in the trench; (b) performing a treatment to modify the conformal liner, wherein an upper portion of the conformal liner is modified more than a lower portion of the conformal liner; (c) repeating steps (a) and (b), wherein a rate of deposition of the conformal material over a non-modified surface of the conformal liner is faster than a rate of deposition of the conformal material over a modified surface of the conformal liner to form a remaining unfilled gap with a V-shape; and (d) depositing a conformal material in the remaining unfilled gap.

In certain embodiments of the method, an initial step of (a) depositing conformal material to form a conformal liner in the trench includes depositing the conformal material along sidewalls and a bottom of the trench.

In certain embodiments of the method, steps (a), (b), and (c) form a liner structure having a minimum thickness over a bottom of the trench of at least 20 nanometers (nm).

In certain embodiments of the method, (b) performing a treatment to modify the conformal liner includes incorporating at least one additional element into the conformal liner.

In certain embodiments of the method, (b) performing a treatment to modify the conformal liner includes performing a N₂/H₂ plasma treatment to incorporate at least one additional element selected from N and H into the conformal liner.

In certain embodiments of the method, (a) depositing conformal material to form a conformal liner in the trench includes depositing silicon nitride by an atomic layer deposition (ALD) process; and (d) depositing a conformal material in the remaining unfilled gap includes depositing silicon oxide or silicon nitride by an atomic layer deposition (ALD) process.

In certain embodiments, the method further includes forming the trench by etching through a gate layer and into a semiconductor substrate disposed under the gate layer.

In another embodiment, a method is provided for filling a trench. The method includes depositing a flowable material to fill a lower portion of the trench with a bottom plug and to form a sidewall member of the flowable material adjacent to a sidewall of the trench and above the bottom plug, wherein the sidewall member has an initial thickness; performing a treatment to shrink the sidewall member from the initial thickness to a reduced thickness, wherein a remaining unfilled gap is defined above the bottom plug and inside the sidewall member; and depositing a conformal material in the remaining unfilled gap.

In certain embodiments, the method further includes depositing conformal material to form a conformal liner along a sidewall and a bottom of the trench before depositing the flowable material. In certain embodiments, the conformal material is an oxidation barrier dielectric layer.

In certain embodiments of the method, an upper portion of the trench has a first width, and the lower portion of the trench has a second width greater than the first width.

In certain embodiments of the method, performing a treatment to shrink the sidewall member from the initial thickness to a reduced thickness includes performing an ultraviolet treatment and/or a thermal anneal treatment.

In certain embodiments of the method, the reduced thickness is from 3 to 20% less than the initial thickness.

In certain embodiments of the method, the flowable material is silicon oxide, and depositing a conformal material in the remaining unfilled gap includes depositing silicon nitride by an atomic layer deposition (ALD) process.

In another embodiment, a method is provided for filling a trench and includes depositing a first conformal material at a first deposition rate and at a first temperature to form a first conformal liner in the trench, wherein a remaining unfilled gap is defined inside the first conformal liner, and depositing a second conformal material at a second deposition rate greater than the first deposition rate and at a second temperature lower than the first temperature to form a second conformal liner in the trench.

In certain embodiments of the method, the first conformal material is silicon nitride and is silicon rich, and the second conformal material is silicon nitride and is nitrogen rich.

In certain embodiments of the method, the first conformal material has a silicon:nitrogen ratio of from 1:1 to 1.2:1, and the second conformal material has a silicon:nitrogen ratio of is from 0.8:1 to 1:1.

In certain embodiments of the method, the first temperature is from 510 to 600° C., and the second temperature is from 400 to 450° C.

In certain embodiments of the method, the first deposition rate is 8 to 10 wafers per hour (WPH) and the second deposition rate is from 10 to 15 WPH.

In certain embodiments, the method further includes forming the trench by etching through a fin structure including nanosheet layers and into a semiconductor substrate disposed under the fin structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present.

What is claimed is:

1. A method for filling a trench, the method comprising:
(a) depositing conformal material to form a conformal liner in the trench;
(b) performing a treatment to modify the conformal liner, wherein an upper portion of the conformal liner is modified more than a lower portion of the conformal liner;
(c) repeating steps (a) and (b), wherein a rate of deposition of the conformal material over a non-modified surface of the conformal liner is faster than a rate of deposition of the conformal material over a modified surface of the conformal liner to form a remaining unfilled gap with a substantially V-shape; and
(d) depositing a conformal material in the remaining unfilled gap.

2. The method of claim 1, wherein an initial step of (a) depositing conformal material to form a conformal liner in the trench comprises depositing the conformal material along sidewalls and a bottom of the trench.

3. The method of claim 1, wherein steps (a), (b), and (c) form a liner structure, wherein the liner structure has a minimum thickness over a bottom of the trench of at least 20 nanometers (nm).

4. The method of claim 1, wherein (b) performing a treatment to modify the conformal liner comprises incorporating at least one additional element into the conformal liner.

5. The method of claim 1, wherein (b) performing a treatment to modify the conformal liner comprises performing a N₂/H₂ plasma treatment to incorporate at least one additional element selected from N and H into the conformal liner.

6. The method of claim 1, wherein:
(a) depositing conformal material to form a conformal liner in the trench comprises depositing silicon nitride by an atomic layer deposition (ALD) process; and
(d) depositing a conformal material in the remaining unfilled gap comprises depositing silicon oxide or silicon nitride by an atomic layer deposition (ALD) process.

7. The method of claim 1, further comprising forming the trench by etching through a gate layer and into a semiconductor substrate disposed under the gate layer.

8. A method for filling a trench, the method comprising:
depositing a flowable material to fill a lower portion of the trench with a bottom plug and to form a sidewall member of the flowable material adjacent to a sidewall of the trench and above the bottom plug, wherein the sidewall member has an initial thickness;
performing a treatment to shrink the sidewall member from the initial thickness to a reduced thickness, wherein a remaining unfilled gap is defined above the bottom plug and inside the sidewall member; and
depositing a conformal material in the remaining unfilled gap.

9. The method of claim 8, further comprising depositing conformal material to form a conformal liner along a sidewall and a bottom of the trench before depositing the flowable material.

10. The method of claim 9, wherein the conformal material is an oxidation barrier dielectric layer.

11. The method of claim 8, wherein an upper portion of the trench has a first width, and wherein the lower portion of the trench has a second width different from the first width.

12. The method of claim 8, wherein performing a treatment to shrink the sidewall member from the initial thickness to a reduced thickness comprises performing an ultraviolet treatment and/or a thermal anneal treatment.

13. The method of claim 8, wherein the reduced thickness is from 3 to 20% less than the initial thickness.

14. The method of claim 8, wherein the flowable material is silicon oxide, and wherein depositing a conformal material in the remaining unfilled gap comprises depositing silicon nitride by an atomic layer deposition (ALD) process.

15. A method for filling a trench, the method comprising:
depositing a first conformal material at a first deposition rate and at a first temperature to form a first conformal liner in the trench, wherein a remaining unfilled gap is defined inside the first conformal liner, and
depositing a second conformal material at a second deposition rate greater than the first deposition rate and at a second temperature lower than the first temperature to form a second conformal liner in the trench.

16. The method of claim 15, wherein the first conformal material is silicon nitride and is silicon rich, and wherein the second conformal material is silicon nitride and is nitrogen rich.

17. The method of claim 16, wherein the first conformal material has a silicon:nitrogen ratio of from 1:1 to 1.2:1, and wherein the second conformal material has a silicon:nitrogen ratio of is from 0.8:1 to 1:1.

18. The method of claim 15, wherein the first temperature is from 510 to 600° C., and wherein the second temperature is from 400 to 450° C.

19. The method of claim 15, wherein the first deposition rate is 8 to 10 wafers per hour (WPH) and wherein the second deposition rate is from 10 to 15 WPH.

20. The method of claim 15, further comprising forming the trench by etching through a fin structure including nanosheet layers and into a semiconductor substrate disposed under the fin structure.
